(19) United States
(12) Patent Application Publication
(10) Pub. No.: US 2011/0279781 A1
(43) Pub. Date: Nov. 17, 2011

(54) PROJECTION SCREEN, PROJECTION SYSTEM AND METHOD FOR MAKING THE PROJECTION SCREEN

(75) Inventors: CHAO-TSANG WEI, Tu-Cheng (TW); GA-LANE CHEN, Santa Clara, CA (US)

(73) Assignee: HON HAI PRECISION INDUSTRY CO., LTD., Tu-Cheng (TW)

(21) Appl. No.: 12/822,193

(22) Filed: Jun. 24, 2010

(30) Foreign Application Priority Data
May 17, 2010 (TW) 99115631

(51) Int. Cl. G03B 21/60; C23C 14/34; B05D 5/06

(52) U.S. Cl. 353/31; 359/443; 427/164; 204/192.1

(57) ABSTRACT

A projection system, projection screen, and method for making the screen are provided. The projection screen includes a flexible transparent substrate having a first surface and an opposite second surface; and a reflective film formed on the second surface of the substrate. The reflective film reflects red, green and blue light, such as from a projector, making it viewable on the screen, and substantially absorbs ambient light other than the above specified light wavelengths, resulting in relatively higher contrast.

### BACKGROUND

1. Technical Field

The present disclosure relates to a projection screen with a reflective film, a projection system using same and a method for making the projection screen.

2. Description of Related Art

Projection screens are key components of projection systems. Projection screens may be transmissive-type (rear projection type) or reflective-type (front projection type).

A typical reflective-type projection screen reflects all the light including the projection light and the ambient visual light in a long wavelength range (380 nm to 780 nm), such that a contrast of the projection may be low. In order to avoid this, the ambient light has to be reduced; however, this may be inconvenient or even uncomfortable for viewers.

What is needed, therefore, is a projection screen, projection system and a method for making the projection screen which can overcome the above shortcomings.

### BRIEF DESCRIPTION OF THE DRAWINGS

Many aspects of the present projection screen, projection system and the present method can be better understood with reference to the following drawings. The components in the drawings are not necessarily drawn to scale, the emphasis instead being placed upon clearly illustrating the principles of the present projection screen, projection system and method. Moreover, in the drawings, like reference numerals designate corresponding parts throughout the several views.

FIG. 1 is a schematic view of a projection system in accordance with an exemplary embodiment, the projection system including a projector and a projection screen.

FIG. 2 shows a reflection characteristic of the projection screen.

### DETAILED DESCRIPTION

Embodiments of the present projection screen, projection system and the present method will now be described in detail below and with reference to the drawings.

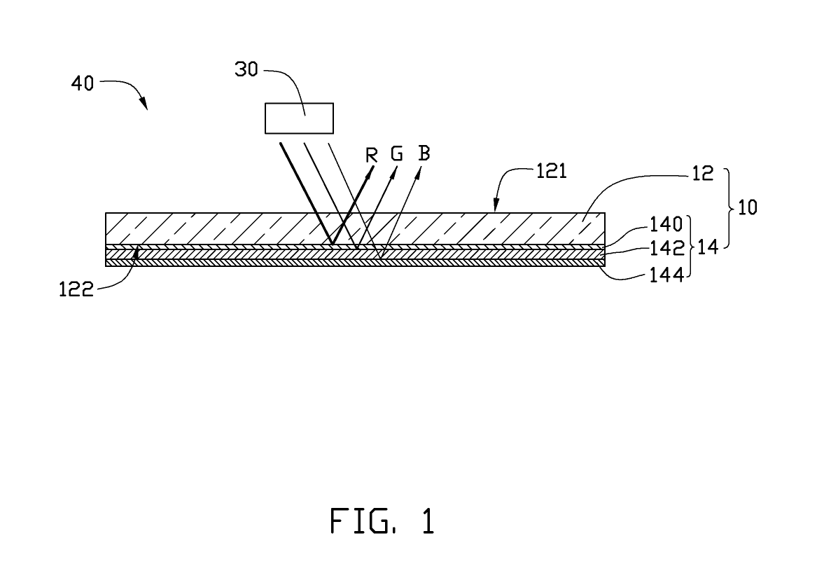

Referring to FIG. 1, a projection system 40 includes a projector 30 and a projection screen 10. The projection screen 10 is a reflective-type screen. The projector 30 is arranged in front of the projection screen 10, i.e., on the viewing side.

The projector 30 provides a mix of red, blue and green light. The projection screen 10 includes a flexible transparent substrate 12, and a reflective film 14. The substrate 12 has a first surface 121 facing the projector 30 and an opposite second surface 122. The substrate 12 is made of polyvinyl butyral (PVB), and has a transmittance for visible light (380 nm to 780 nm wavelength) greater than 80%. The reflective film 14 is formed on the second surface 122.

The reflective film 14 includes a first layer 140, a second layer 142 and a third layer 144. The first layer 140 is the innermost layer, and the third layer 144 is the outermost layer. The first layer 140 is made of aluminum, the second layer 142 is made of alumina, and the third layer 144 is made of chromium.

Thickness of the first layer 140, the second layer 142, and the third layer 144 are determined by the following formula nd=λ(N±¼). Wherein N is natural number, λ is wavelength of the light to be reflected, d is thickness of the layer, n is refractive index of the layer, and nd is called optical thickness of the layer. After the material of the layer is selected, the light wavelength is determined, the thickness n of the layer can be determined by selecting a natural number N.

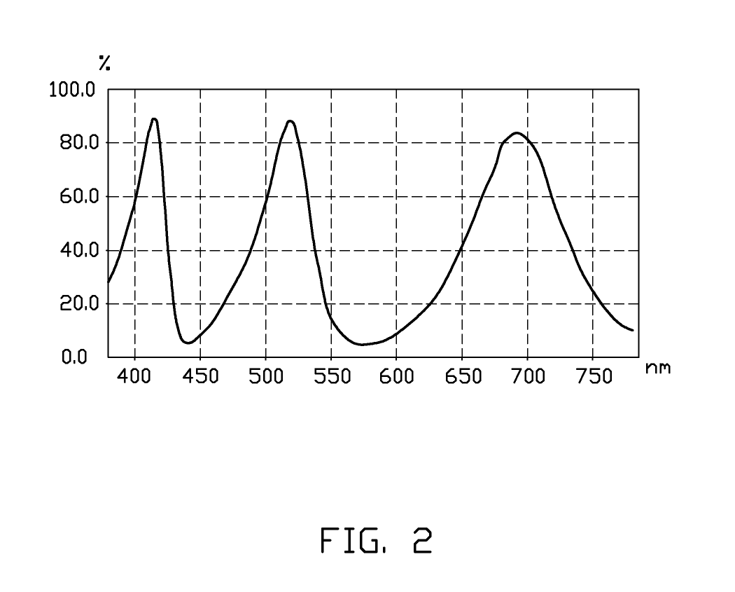

In the present embodiment, a thickness range of the first layer is between 20 and 200 nm, a thickness range of the second layer is between 600 nm and 650 nm; and a thickness range of the third layer is between 2 nm and 10 nm. Referring to FIG. 2, the reflective film 14 only reflects the red light (640 nm to 780 nm wavelength), green light (500 nm to 560 nm wavelength), and blue light (400 nm to 470 nm wavelength), thus a higher contrast of the projected images can be achieved. In the present embodiment, the first layer 140 can only reflect the red light, the second layer 142 can only reflect the green light, and the third layer 144 can only reflect the blue light. The reflective film 14 preferably substantially absorbs light other than the RGB light of the specified ranges of wavelengths, then can enhance the contrast of projected images.

Because the reflective film 14 is formed on the second surface 122 which is at the back side of the projection screen 10, the first surface 121, which is the outermost layer, protects the reflective film 14, particularly during cleaning of the projection screen 10.

A method for making the projection screen 10 includes the following steps. First, a flexible transparent substrate is provided. The substrate has a transmittance for visible light greater than 80%, and has a first surface and an opposite second surface. The substrate may be made from a material such as polyvinyl butyral. Second, a first layer is formed on the second surface of the substrate by a sputtering deposition method. Third, a second layer on the first layer is formed on the first layer. Fourth, a third layer is formed on the second layer by the sputtering deposition method. The first layer is made of aluminum, the second layer is made of alumina and the third layer is made of chromium. After the second layer is formed, a thickness range of the aluminum layer is between 20 and 200 nm, and a thickness range of the alumina layer is between 600 and 650 nm; after the third layer is finished, a thickness range of the chromium layer is between 2 and 10 nm.

In particular, the second layer can be formed by oxidizing a part of the first layer, or be made by the sputtering deposition method. The first, second and third layers form a reflective film on the second surface of the substrate.

It is understood that the above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A projection screen for displaying an image projected as a combination of first color light, second color light and third color light, the projection screen comprising:
a flexible transparent substrate having a first surface for receiving the first, second and third color light, and an opposite second surface; and
a reflective film formed on the second surface of the substrate, the reflective film configured for reflecting only the first, second and third color light to form the projected image.

2. The projection screen of claim 1, wherein the substrate has a transmittance of greater than 80% for visible light.

3. The projection screen of claim 1, wherein the first color light is red light with a wavelength range between 640 nm and 780 nm, the second color light is green light with a wavelength range between 500 nm and 560 nm, and the third color light is blue light with a wavelength range between 400 nm and 470 nm.

4. The projection screen of claim 1, wherein the substrate is made of polyvinyl butyral.

5. The projection screen of claim 1, wherein the reflective film comprises a first layer made of aluminum with a thickness in a range from 20 nm and 200 nm, a second layer made of alumina with a thickness in a range from 600 nm and 650 nm, a third layer made of chromium with a thickness in a range from 2 nm and 10 nm.

6. A projection system, comprising:
a projector for emitting first color light, second color light and third color light; and
a projection screen comprising
a flexible transparent substrate having a first surface facing the projector and an opposite second surface; and
a reflective film formed on the second surface, the reflective film configured for only reflecting the first color light, the second color light and the third color light.

7. The projection system of claim 6, wherein the substrate has a transmittance of greater than 80% for visible light.

8. The projection screen of claim 6, wherein the first color light is red light with a wavelength range between 640 nm and 780 nm, the second color light is green light with a wavelength range between 500 nm and 560 nm, and the third color light is blue light with a wavelength range between 400 nm and 470 nm.

9. The projection system of claim 6, wherein the substrate is made of polyvinyl butyral.

10. The projection system of claim 6, wherein the reflective film comprises a first layer made of aluminum with a thickness in a range from 20 nm and 200 nm, a second layer made of alumina with a thickness in a range from 600 nm and 650 nm, a third layer made of chromium with a thickness in a range from 2 nm and 10 nm.

11. A method for making a projection screen for displaying an image projected as a combination of first color light, second color light and third color light, the method comprising:
providing a flexible transparent substrate, the substrate having a transmittance of greater than 80% for visible light, the substrate having a first surface and an opposite second surface;
forming a first layer on the second surface of the substrate for only reflecting the first color light;
forming a second layer on the first layer for only reflecting the second color light; and
forming a third layer on the second layer for only reflecting the third color light.

12. The method of claim 11, wherein the substrate is made of polyvinyl butyral.

13. The method of claim 11, wherein the first layer is made of aluminum, the second layer is made of alumina and the third layer is made of chromium.

14. The method of claim 13, wherein the second layer is formed by sputtering, a thickness of the first layer is in a range from 20 nm and 200 nm, a thickness range of the second layer is from 600 nm and 650 nm; and a thickness of the third layer is in a range from 2 nm and 10 nm.

15. The method of claim 13, wherein the second layer is formed by oxidizing a part of the first layer.

16. The method of claim 14, wherein after the second layer is formed, a thickness of the aluminum is in a range from 20 nm and 200 nm, and a thickness of the alumina is in a range from 600 nm and 650 nm; after the third layer is finished, a thickness of the chromium is in a range from 2 nm and 10 nm.
